(19) United States
(12) Patent Application Publication
(10) Pub. No.: US 2025/0098514 A1
(43) Pub. Date: Mar. 20, 2025

(54) DISPLAY DEVICE

(71) Applicant: Samsung Display Co., LTD., Yongin-si (KR)

(72) Inventors: Hyun KIM, Yongin-si (KR); Seung Min LEE, Yongin-si (KR)

(21) Appl. No.: 18/814,352

(22) Filed: Aug. 23, 2024

(30) Foreign Application Priority Data
Sep. 19, 2023 (KR) 10-2023-0124489

(51) Int. Cl. H10K 77/10; H10K 59/124; H10K 102/00

(52) U.S. Cl. CPC H10K 77/111; H10K 59/124; H10K 2102/311

(57) ABSTRACT

A display device includes: a first substrate having a main region, a pad area, and a bending area therebetween; and a second substrate on the main and pad regions of the first substrate opposite to a side where a thin film transistor layer is arranged. The second substrate includes a first sub-substrate overlapping the main region and a second sub-substrate spaced apart from the first sub-substrate with the bending area therebetween and overlapping the pad area. The first sub-substrate has: a first surface facing the first substrate; a second surface opposite to the first surface; a first inclined surface facing the bending area and extending to the first surface; and a second inclined surface extending between the second surface and the first inclined surface. The first surface has an uneven structure.

### CROSS-REFERENCE TO RELATED APPLICATION

The present application claims priority to and the benefit of Korean Patent Application No. 10-2023-0124489, filed on Sep. 19, 2023, in the Korean Intellectual Property Office, the entire disclosure of which is incorporated herein by reference.

### BACKGROUND

### 1. Field

Aspects of embodiments of the present disclosure relate to a display device.

### 2. Description of the Related Art

With the advance of an information-oriented society, there is an increasing demand for display devices that display images in various ways. The display device may be a flat panel display device, such as a liquid crystal display, a field emission display, and a light emitting display.

The display device generally has a display area for displaying an image and a non-display area disposed around the display area, for example, to surround a periphery of the display area. Recently, a width of the non-display area has been gradually reduced to increase immersion in the display area and enhance the aesthetics of the display device.

### SUMMARY

Embodiments of the present disclosure mitigate or prevent a defect that may occur when a first substrate and a second substrate are detached when the display panel is bent.

However, aspects and features of the present disclosure are not limited to those set forth herein. The above and other aspects and features of the present disclosure will become more apparent to one of ordinary skill in the art to which the present disclosure pertains by referencing the detailed description of the present disclosure given below.

According to an embodiment of the present disclosure, a display device includes: a first substrate having a main region, a pad area, and a bending area between the main region and the pad area; a thin film transistor layer on the main region of the first substrate; and a second substrate on the main region and the pad area of the first substrate on a side opposite to a side where the thin film transistor layer is arranged. The second substrate includes a first sub-substrate overlapping the main region and a second sub-substrate spaced apart from the first sub-substrate with the bending area therebetween and overlapping the pad area. The first sub-substrate has: a first surface facing the first substrate; a second surface opposite to the first surface; a first inclined surface facing the bending area and extending to the first surface; and a second inclined surface connecting the second surface to the first inclined surface. An inclination angle formed between the first surface and the first inclined surface and an inclination angle formed between the second surface and the second inclined surface are obtuse angles, and the first surface has an uneven structure.

The uneven structure of the first surface may not overlap the bending area.

The uneven structure of the first surface may have a shape in which protrusions and recesses are randomly arranged.

The first substrate and the second substrate may be in contact with each other.

A contact area between the first substrate and the second substrate may be increased due to the uneven structure of the first surface.

The uneven structure may have a root mean square (RMS) roughness of 3.5 nm or more.

The display may further include a bending protection layer on the bending area of the first substrate. The bending protection layer may overlap the first inclined surface and the second inclined surface in a direction normal to the first substrate.

The bending protection layer may overlap the main region, and the bending protection layer may overlap the uneven structure of the first surface in the direction normal to the first substrate.

The second sub-substrate may have a third surface facing the first substrate; a fourth surface opposite to the third surface; a third inclined surface facing the bending area and extending to the third surface; and a fourth inclined surface connecting the fourth surface to the third inclined surface. An inclination angle formed between the third surface and the third inclined surface and an inclination angle formed between the fourth surface and the fourth inclined surface may be obtuse angles, and the third surface may have an uneven structure.

The third inclined surface and the fourth inclined surface may face the first inclined surface and the second inclined surface.

The bending protection layer may overlap the pad area, and the uneven structure of the third surface may overlap the bending protection layer in a direction perpendicular to the first substrate.

The second substrate may have a first edge surface overlapping an end of the first substrate and extending to the first surface, and an undercut may be formed between the first edge surface and the first substrate.

An inclination angle formed between the first surface and the first edge surface inside the second substrate may be an obtuse angle.

The second substrate may have a thickness of 200 μm or less.

According to another embodiment of the present disclosure, a display device includes: a first substrate having a main region including a display area and a non-display area, a pad area, and a bending area between the non-display area and the pad area; a display element layer on the display area of the first substrate; and a second substrate on the first substrate on a side opposite to a side where the display element layer is arranged. The second substrate includes a first sub-substrate overlapping the main region and a second sub-substrate overlapping the pad area and spaced apart from the first sub-substrate with the bending area therebetween. The first sub-substrate has a first surface facing the first substrate and having an uneven structure, the second sub-substrate has a second surface facing the first substrate and having an uneven structure, and in a plan view, the uneven structure of the first surface and the uneven structure of the second surface are spaced apart from each other with the bending area therebetween.

The first surface may include a first portion having the uneven structure and a second portion which does not have the uneven structure. The first portion may overlap the non-display area, and the second portion may overlap the display area.

The first portion may not overlap the display area in the plan view, and the first portion may have a mesh shape in the plan view.

The uneven structure of the first surface may overlap the display area, and in the plan view, the uneven structure of the first surface may overlap the display element layer in a direction normal to the first substrate.

The display device may further include a bending protection layer on the non-display area, the bending area, and the pad area of the first substrate. In the plan view, the bending protection layer may overlap the uneven structure of the first surface and the uneven structure of the second surface in a direction normal to the first substrate.

The first substrate and the second substrate may be in contact with each other, and the uneven structure may increase an adhesive area between the first substrate and the second substrate.

In a display device, according to an embodiment of the present disclosure, a contact area between a first substrate and a second substrate may be increased by forming an uneven surface structure on the first substrate by using a laser. Accordingly, when a display panel included in the display device is bent, the first substrate and the second substrate may not detach, thereby preventing creation of a defect.

However, aspects and features of the present disclosure are not limited to those described above, and various other aspects and features are incorporated herein.

### BRIEF DESCRIPTION OF THE DRAWINGS

The above and other aspects and features of the present disclosure will become more apparent by describing, in detail, embodiments thereof with reference to the attached drawings, in which:

FIG. 1 is a perspective view of an electronic device according to one embodiment;

FIG. 2 is a perspective view of a display device included in the electronic device shown in FIG. 1;

FIG. 3 is a schematic cross-sectional view of the display device shown in FIG. 2;

FIG. 4 is a cross-sectional view of the display device shown in FIG. 3 in a bent configuration;

FIG. 5 is a schematic plan view of the display panel shown in FIG. 2;

FIG. 6 is an enlarged plan view of the area ‘A’ in FIG. 5;

FIG. 7 is a schematic cross-sectional view of the display panel taken along the line Y1-Y1′ in FIG. 6;

FIG. 8 is an enlarged cross-sectional view illustrating a top surface of the first sub-substrate shown in FIG. 7;

FIG. 9 is a cross-sectional view of a display device taken along the line Y3-Y3′ of FIG. 6;

FIG. 10 is an enlarged cross-sectional view illustrating a top surface of the second sub-substrate shown in FIG. 9;

FIG. 11 is an enlarged plan view of the area ‘B’ in FIG. 5;

FIG. 12 is a cross-sectional view of a display device taken along the line X1-X1′ in FIG. 11;

FIG. 13 is an enlarged cross-sectional view illustrating a top surface of a first sub-substrate shown in FIG. 12;

FIG. 14 is a plan view illustrating a schematic structure where an uneven structure of a first substrate overlaps in a plan view;

FIG. 15 is an enlarged cross-sectional view illustrating the top surface of the first sub-substrate shown in FIG. 7 according to another embodiment;

FIG. 16 is a plan view illustrating a schematic structure where the uneven structure included in the first substrate shown in FIG. 15 overlaps in a plan view;

FIG. 17 is an enlarged cross-sectional view illustrating the top surface of the first sub-substrate shown in FIG. 7 according to another embodiment;

FIG. 18 is an enlarged cross-sectional view illustrating the top surface of the first sub-substrate shown in FIG. 12 according to another embodiment; and

FIG. 19 is a plan view showing a schematic structure where an uneven structure included in the first substrate shown in FIGS. 17 and 18 overlaps.

### DETAILED DESCRIPTION

The present disclosure will now be described more fully herein with reference to the accompanying drawings, in which some embodiments thereof are shown. The present disclosure may, however, be embodied in different forms and should not be construed as limited to the embodiments set forth herein. Rather, these embodiments are provided so that this disclosure will be thorough and complete and will fully convey the present disclosure to those skilled in the art.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the inventive concept pertains. It is also to be understood that terms defined in commonly used dictionaries should be interpreted as having meanings consistent with the meanings in the context of the related art, and are expressly defined herein unless they are interpreted in an ideal or overly formal sense.

Hereinafter, embodiments of the present disclosure will be described in detail with reference to the accompanying drawings.

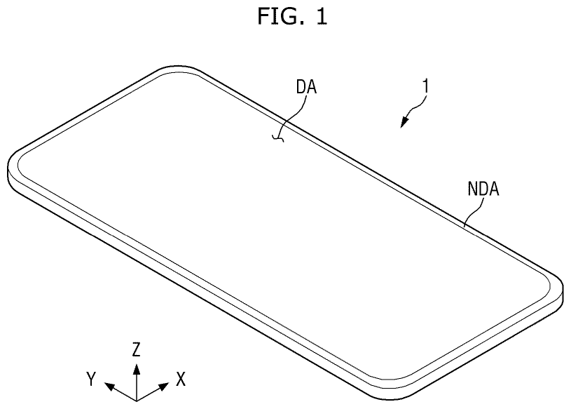

FIG. 1 is a perspective view of an electronic device according to an embodiment.

Referring to FIG. 1, an electronic device 1 is configured to display a moving image and/or a still image. The electronic device 1 may refer to any electronic device providing (or including) a display screen. Examples of the electronic device 1 may include a television, a laptop computer, a monitor, a billboard, an Internet-of-Things (IoT) device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder, and the like, which provide a display screen.

FIG. 1 defines a first direction (e.g., an X-axis direction), a second direction (e.g., a Y-axis direction), and a third direction (e.g., a Z-axis direction). The first direction (e.g., the X-axis direction) and the second direction (e.g., the Y-axis direction) may be perpendicular to each other, the first direction (e.g., the X-axis direction) and the third direction (e.g., the Z-axis direction) may be perpendicular to each other, and the second direction (e.g., the Y-axis direction) and the third direction (e.g., the Z-axis direction) may be perpendicular to each other. It may be understood that the first direction (e.g., the X-axis direction) refers to a horizontal direction in the drawing, the second direction (e.g., the Y-axis direction) refers to a vertical direction in the drawing, and the third direction (e.g., the Z-axis direction) refers to an upward and downward direction (e.g., a thickness direction) in the drawing. In the following specification, unless otherwise stated, “direction” may refer to both directions extending along the direction. Further, to distinguish between opposite “directions” extending in both directions, one side will be referred to as “one side in the direction” and the other side will be referred to as “the other side in the direction.” Referring to FIG. 1, a direction in which the arrow indicating a direction is directed is referred to as the one side, and an opposite direction thereto is referred to as the other side.

Hereinafter, for simplicity of description, when referring to the electronic device 1 or the surfaces of each member constituting the electronic device 1, one surface facing one side in the direction in which the image is displayed, that is, the third direction (e.g., the Z-axis direction) is referred to as a top surface, and the opposite surface of the one surface is referred to as the other surface. However, the present disclosure is not limited thereto, and the one surface and the other surface of the member may be referred to as a front surface and a rear surface, respectively, or may also be referred to as a first surface or a second surface. In addition, in describing the relative position of each of the members of the electronic device 1, one side in the third direction (e.g., the Z-axis direction) may be referred to as an upper side and the other side in the third direction (e.g., the Z-axis direction) may be referred to as a lower side.

The shape of the electronic device 1 may be variously modified. For example, the electronic device 1 may have a shape, such as a rectangular shape elongated in a horizontal direction, a rectangular shape elongated in a vertical direction, a square shape, a quadrilateral shape with rounded corners (e.g., vertices), other polygonal shapes, and a circular shape.

The electronic device 1 may have a display area DA and a non-display area NDA. The display area DA is an area where an image is displayed, and the non-display area NDA is an area where an image is not displayed. The display area DA may also be referred to as an active region, and the non-display area NDA may also be referred to as a non-active region. The display area DA may substantially occupy the center of the electronic device 1.

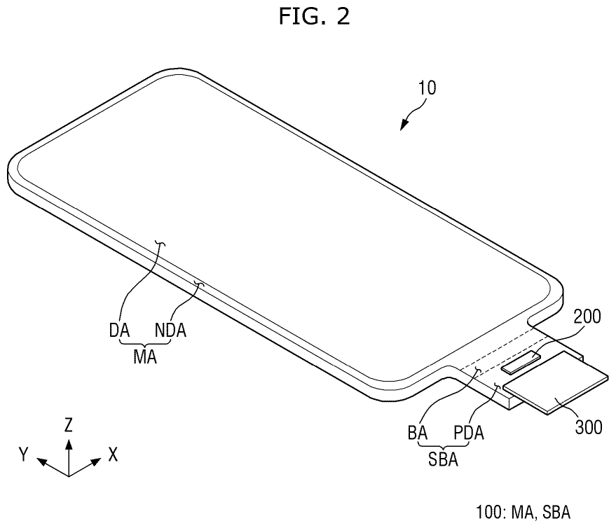

FIG. 2 is a perspective view of a display device 10 included in the electronic device 1 according to an embodiment.

Referring to FIG. 2, the display device 10, according to an embodiment, is a device for displaying a moving image and/or a still image. The display device 10 may be used as a display screen of various devices, such as a television, a laptop computer, a monitor, a billboard, and an Internet-of-Things (IoT) device, as well as portable electronic devices, such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10, according to an embodiment, may be a light emitting display device, such as an organic light emitting display using an organic light emitting diode, a quantum dot light emitting display including a quantum dot light emitting layer, an inorganic light emitting display including an inorganic semiconductor, and a micro or nano light emitting display using a micro or nano light emitting diode (LED). In the following description, the display device 10 is illustrated and described as being an organic light emitting display device, but the present disclosure is not limited thereto.

The display device 10, according to an embodiment, includes a display panel 100, a display driver 200, and a circuit board 300.

The display panel 100 may have a rectangular shape, in a plan view, having short sides in a first direction (e.g., the X-axis direction) and long sides in a second direction (e.g., the Y-axis direction) crossing the first direction. A corner at where the short side in the first direction (e.g., the X-axis direction) and the long side in the second direction (e.g., the Y-axis direction) meet may be right-angled or rounded with a curvature. The planar shape of the display panel 100 is not limited to the rectangular shape and may be formed in another polygonal shape, a circular shape, or an elliptical shape.

The display panel 100 may be flat but is not limited thereto. For example, the display panel 100 may have a curved portion formed at left and right ends (or sides) and may have a constant curvature or a varying curvature. In addition, the display panel 100 may be flexible so that it can be curved, bent, folded, or rolled.

The display panel 100 may have a main region MA and a sub-region SBA.

The main region MA may include the display area DA including pixels for displaying an image and the non-display area NDA disposed around (e.g., around a periphery of) the display area DA.

The display area DA may emit light from a plurality of open areas or a plurality of emission areas, to be described later. For example, the display area DA may include a pixel circuit including switching elements, a pixel defining layer defining an emission area or an open area, and a self-light emitting element. For example, the self-light emitting element may include at least one of an organic light emitting diode (LED) including an organic light emitting layer, a quantum dot LED including a quantum dot light emitting layer, an inorganic LED including an inorganic semiconductor, or a micro LED, but it is not limited thereto. In the following drawings, an embodiment in which the self-light emitting element is an organic light emitting diode is illustrated as an example.

The non-display area NDA may be an area outside the display area DA. The non-display area NDA may be defined as an edge area of the main region MA of the display panel 100. The non-display area NDA may include a plurality of wires that connect the display driver 200 to a plurality of pixels PX. The non-display area NDA may be an area extending from the sub-region SBA.

The sub-region SBA may be a region extending from one side of the main region MA. The sub-region SBA may include a bending area BA and a pad area PDA.

The bending area BA may be located between the non-display area NDA and the pad area PDA. The bending area BA may be an area that is bent. The bending area BA may include a flexible material, which can be bent, folded or rolled. For example, when the bending area BA of the display panel 100 is bent, the display driver 200 and the circuit board 300 located in the pad area PDA may overlap the main region MA of the display panel 100 in the third direction (e.g., the Z-axis direction).

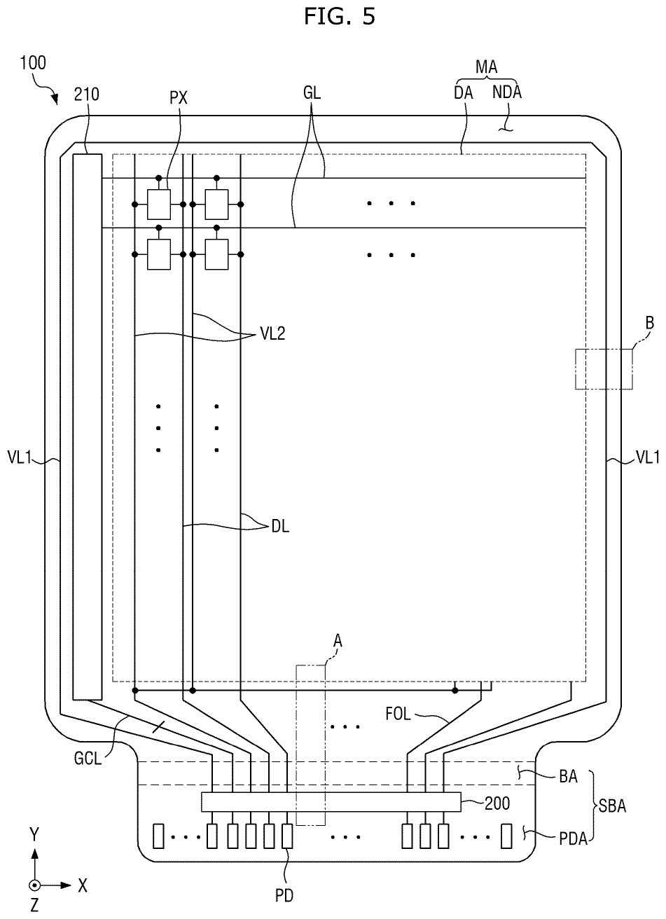

The pad area PDA may be a portion extending from the bending area BA. The pad area PDA may include the display driver 200, the circuit board 300, and a display pad PD (see, e.g., FIG. 5). The display pad PD may be connected to the circuit board 300.

The display driver 200 may output signals and voltages for driving the display panel 100. The display driver 200 may supply data voltages to data lines. The display driver 200 may supply a power voltage to the power line and may supply a gate control signal to a gate driver 210. The display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-region SBA and may overlap the main region MA in the thickness direction by bending of the sub-region SBA. In another embodiment, the display driver 200 may be mounted on the circuit board 300.

The circuit board 300 may be attached to the display pad of the display panel 100 by using an anisotropic conductive film (ACF). Lead lines of the circuit board 300 may be electrically connected to the display pad of the display panel 100. The circuit board 300 may be a flexible printed circuit board, a printed circuit board, or a flexible film such as a chip on film.

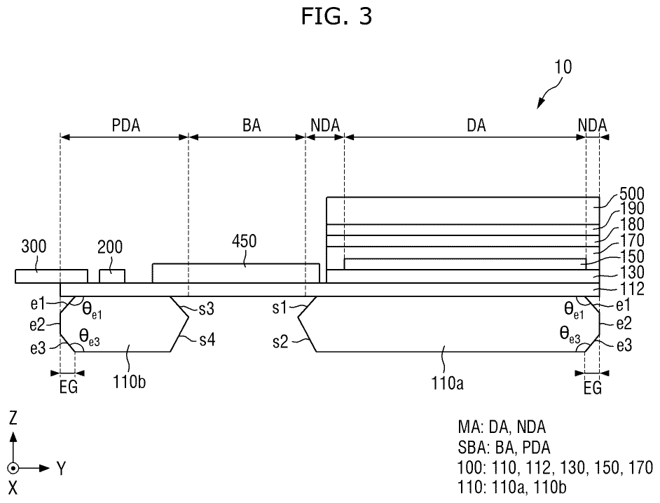

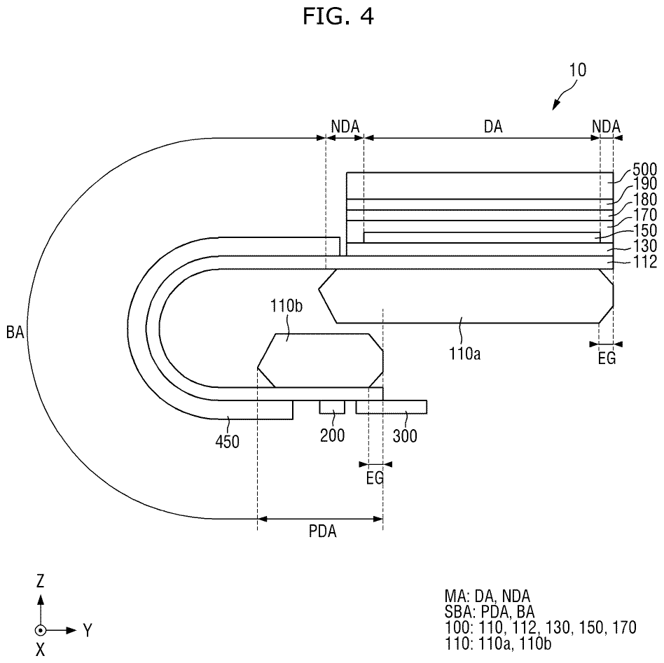

FIG. 3 is a schematic cross-sectional view of the display device 10 shown in FIG. 2, and FIG. 4 is a cross-sectional view of the display device 10 shown in FIG. 3 in a bent configuration or state.

Referring to FIG. 3, the display device 10, according to an embodiment, may include the display panel 100, a touch sensor layer 180, a polarizing film 190, and a cover window 500. The display panel 100 may include a first substrate 110, a second substrate 112, a thin film transistor layer 130, a display element layer 150, and a thin film encapsulation layer 170.

The first substrate 110 may include (or may be formed of) a hard (or stiff) material. For example, the first substrate 110 may be made of glass. The first substrate 110 may be formed of ultra-thin glass (UTG) having a thickness in a range of approximately 200 μm or less.

In the first substrate 110, according to an embodiment, a portion thereof overlapping the bending area BA may be etched during a manufacturing process to form the bending area BA. Accordingly, the first substrate 110 may be divided into (or separated into) a first sub-substrate 110a and a second sub-substrate 110b. The first sub-substrate 110a and the second sub-substrate 110b may be spaced apart from each other to expose the bending area BA therebetween.

The first sub-substrate 110a may be disposed to overlap the main region MA, and the second sub-substrate 110b may be disposed to overlap the pad area PDA of the sub-region SBA. However, the present disclosure is not limited thereto, and the first sub-substrate 110a and the second sub-substrate 110b may include all structures disposed to be spaced apart from each other in a portion overlapping the bending area BA.

In some embodiments, the first sub-substrate 110a may have a first inclined surface s1 and a second inclined surface s2 toward (e.g., facing) the bending area BA. The first inclined surface s1 and the second inclined surface s2 may be formed by an etching process during the manufacturing process. For example, the first inclined surface s1 and the second inclined surface s2 may be formed by removing a portion of the first substrate 110 overlapping the bending area BA during the manufacturing process. Depending on the degree to which the first inclined surface s1 and the second inclined surface s2 are etched by an etching solution, an undercut may be formed between the second substrate 112 and the first inclined surface s1, and the first inclined surface s1 and the second inclined surface s2 may be extended, forming angles (e.g., predetermined angles).

In some embodiments, the second sub-substrate 110b may have a first inclined surface s3 and a second inclined surface s4 toward (e.g., facing) the bending area BA. The first inclined surface s3 and the second inclined surface s4 may be formed by an etching process during the manufacturing process. For example, the first inclined surface s3 and the second inclined surface s4 may be formed by removing a portion of the first substrate 110 overlapping the bending area BA during the manufacturing process. Depending on the degree to which the first inclined surface s3 and the second inclined surface s4 are etched by an etching solution, an undercut may be formed between the second substrate 112 and the first inclined surface s3, and the first inclined surface s3 and the second inclined surface s4 may be extended, forming angles (e.g., predetermined angles). The first inclined surface s1 and the second inclined surface s2 of the first sub-substrate 110a and the first inclined surface s3 and the second inclined surface s4 of the second sub-substrate 110b may face each other with the bending area BA interposed therebetween.

In some embodiments, the display panel 100 may have an edge portion EG. The edge portion EG may imply (or may refer to) an end portion of the display panel 100. For example, the edge portion EG of the display panel 100 may imply a portion overlapping the outer portion of the display device 10. For example, in a plan view, the edge portion EG of the display panel 100 may be an outer portion surrounding (e.g., extending around a periphery of) the display device 10 while overlapping the main region MA and the sub-region SBA.

In some embodiments, the first substrate 110 may include a first edge surface e1, a second edge surface e2, and a third edge surface e3 overlapping (or at) the edge portion EG of the display panel 100. As an example, the first sub-substrate 110a of the display device 10 may have the first edge surface e1, the second edge surface e2, and the third edge surface e3 overlapping the non-display area NDA, and the second sub-substrate 110b may have the first edge surface e1, the second edge surface e2, and the third edge surface e3 overlapping the pad area PDA. The first edge surface e1 and the third edge surface e3, according to an embodiment, may be connected by the second edge surface e2, but the present disclosure is not limited thereto. Depending on the manufacturing process, the first edge surface e1 and the third edge surface e3 may be directly connected (e.g., the second edge surface e2 may be omitted).

The first edge surface e1, the second edge surface e2, and the third edge surface e3 overlapping the edge portion EG of the display panel 100 may be formed by an etching process during the manufacturing process of the display device 10. As described above, during the manufacturing process of the display device 10, a portion of the first substrate 110 overlapping the bending area BA is removed through the etching process. At the same time, a portion of the first substrate 110 overlapping the edge portion EG of the display panel 100 may also be etched.

In some embodiments, the first edge surface e1 and the third edge surface e3 may be inclined surfaces. As an example, an inclination angle θe₁ formed between the first edge surface e1 and the top surface of the first sub-substrate 110a facing the second substrate 112, and an inclination angle θe₃ formed between the third edge surface e3 and the bottom surface of the first sub-substrate 110a opposite to the top surface of the first sub-substrate 110a may be obtuse angles. In addition, the inclination angle θe₁ formed by the first edge surface e1 and the top surface of the second sub-substrate 110b facing the second substrate 112, and the inclination angle θe₃ formed by the third edge surface e3 and the bottom surface of the second sub-substrate 110b facing the top surface of the second sub-substrate 110b may be obtuse angles.

In some embodiments, an undercut may be formed between the second substrate 112 and the first edge surface e1 of the first sub-substrate 110a. The undercut formed between the second substrate 112 and the first sub-substrate 110a may overlap the second substrate 112, the thin film transistor layer 130, the thin film encapsulation layer 170, the touch sensor layer 180, the polarizing film 190, and the cover window 500 located thereabove in the third direction (e.g., the Z-axis direction).

In addition, an undercut may also be formed between the second substrate 112 and the first edge surface e1 of the second sub-substrate 110b. The undercut formed between the second substrate 112 and the second sub-substrate 110b may overlap the second substrate 112 and the circuit board 300 located thereabove in the third direction (e.g., the Z-axis direction).

The second substrate 112 may be positioned on the first substrate 110. The second substrate 112 may be positioned to overlap the main region MA and the sub-region SBA. The second substrate 112 may be made of a flexible material. The second substrate 112 may be formed of a polymer resin having a thickness less than that of the first substrate 110. For example, the second substrate 112 may have a thickness of about 20 μm. The second substrate 112 may be formed of an organic material, such as an acryl resin, an epoxy resin, a phenolic resin, a polyamide resin, a polyimide resin, and the like. When the second substrate 112 is made of a polymer resin, it may be referred to as a plastic substrate.

The thin film transistor layer 130 may be located on the second substrate 112. The thin film transistor layer 130 may be positioned to overlap the non-display area NDA and the display area DA of the main region MA. The thin film transistor layer 130 may include a plurality of thin film transistors and a plurality of wires.

The display element layer 150 may be disposed on the thin film transistor layer 130. The display element layer 150 may be positioned to overlap the display area DA of the main region MA. The display element layer 150 may be a layer that displays an image. The display element layer 150 may include a light emitting element that emits light by using a pixel electrode, a light emitting layer, and a common electrode, and a plurality of wires that drive the light emitting element.

The thin film encapsulation layer 170 may be disposed on the display element layer 150. The thin film encapsulation layer 170 may be positioned to overlap the non-display area NDA and the display area DA of the main region MA. The thin film encapsulation layer 170 may prevent oxygen or moisture from permeating into the display element layer 150.

The touch sensor layer 180 may be disposed on the thin film encapsulation layer 170. The touch sensor layer 180 may be positioned to overlap the display area DA and the non-display area NDA of the main region MA. The touch sensor layer 180 may sense a user's touch by using touch wires.

The polarizing film 190 may be disposed on the touch sensor layer 180. The polarizing film 190 may be positioned to overlap the display area DA and the non-display area NDA of the main region MA. The polarizing film 190 may include a first base member, a linear polarization plate, a phase retardation film, such as a quarter-wave plate (A/4 plate), and a second base member to reduce reflection of external light. The first base member, the phase retardation film, the linear polarization plate, and the second base member of the polarizing film 190 may be sequentially stacked on the touch sensor layer 180.

The cover window 500 may be disposed on the polarizing film 190. The cover window 500 may be positioned to overlap the display area DA and the non-display area NDA of the main region MA. The cover window 500 may be attached on (or attached to) the polarizing film 190 by a transparent adhesive member, such as an optically clear adhesive (OCA) film.

A bending protection layer 450 may be positioned on the second substrate 112. The bending protection layer 450 may be positioned to overlap the bending area BA. The bending protection layer 450 may protect the lower structure of the display panel 100 overlapping the bending area BA when the display panel 100 is bent. As shown, the bending protection layer 450 may overlap the non-display area NDA and the pad area PDA. However, the present disclosure is not limited thereto, and the bending protection layer 450 may be positioned to overlap only the bending area BA.

The bending protection layer 450 may include a synthetic resin. As an example, the bending protection layer 450 may include at least one of acrylonitrile butadiene styrene copolymer (ABS), urethane acrylate (UA), polyurethane (PU), polyethylene (PE), ethylene vinyl acetate (EVA), or polyvinyl chloride (PVC).

The display driver 200 and the circuit board 300 may be located on the second substrate 112. The display driver 200 and the circuit board 300 may be positioned to overlap the pad area PDA. The display driver 200 may be located between the bending protection layer 450 and the circuit board 300 in the second direction (e.g., the Y-axis direction), while being spaced apart from the bending protection layer 450 and the circuit board 300 in the second direction (e.g., the Y-axis direction). One side of the circuit board 300 in the second direction (e.g., the Y-axis direction) may be positioned in contact with the second substrate 112, and the other side thereof in the second direction (e.g., the Y-axis direction) may not be in contact with (e.g., may extend beyond) the second substrate 112.

Referring to FIG. 4, in the display device 10, a portion of the display panel 100 overlapping the bending area BA may be bent. When the display panel 100 overlapping the bending area BA is bent, the pad area PDA of the display device 10 may overlap the main region MA in the third direction (e.g., the Z-axis direction). In addition, when the display device 10 is bent, the first sub-substrate 110a and the second sub-substrate 110b may overlap each other in the third direction (e.g., the Z-axis direction).

FIG. 5 is a schematic plan view of the display panel 100 shown in FIG. 2.

Referring to FIG. 5, the display panel 100 may include the plurality of pixels PX, a plurality of gate lines GL, a plurality of data lines DL, and a plurality of second power lines VL2 overlapping the display area DA of the main region MA.

Each of the plurality of pixels PX may be defined as a minimum light emitting unit. The plurality of pixels PX may respectively constitute emission areas EA1, EA2, EA3, and EA4, to be described later.

The plurality of gate lines GL may supply the gate signals received from the gate driver 210 to the plurality of pixels PX. The plurality of gate lines GL may extend in the first direction (e.g., the X-axis direction) and may be spaced apart from each other in the second direction (e.g., the Y-axis direction) crossing the first direction.

The plurality of data lines DL may supply the data voltages received from the display driver 200 to the plurality of pixels PX. The plurality of data lines DL may extend in the second direction (e.g., the Y-axis direction) and may be spaced apart from each other in the first direction (e.g., the X-axis direction).

The plurality of second power lines VL2 may supply the power voltage received from the display driver 200 to the plurality of pixels PX. The power voltage may be at least one of a driving voltage, an initialization voltage, or a reference voltage. The plurality of second power lines VL2 may extend in the second direction (e.g., the Y-axis direction) and may be spaced apart from each other in the first direction (e.g., the X-axis direction).

The display panel 100 may include a first power line VL1, the gate driver 210, a plurality of fan-out lines FOL, and a plurality of gate control lines GCL overlapping the non-display area NDA of the main region MA, and may include the first power line VL1, the plurality of fan-out lines FOL, and the plurality of gate control lines GCL overlapping the bending area BA of the sub-region SBA.

The gate driver 210 may generate a plurality of gate signals based on the gate control signal and may sequentially supply the plurality of gate signals to the plurality of gate lines GL according to an order (e.g., a set order).

The first power line VL1 may surround (e.g., may extend around) the display area DA and may be disposed in the non-display area NDA. The first power line VL1 may supply the power voltage received from the display driver 200 to the plurality of pixels PX. The power voltage may be a low potential power voltage (ELVSS).

The plurality of fan-out lines FOL may extend from the display driver 200 to the display area DA. The fan-out lines FOL may supply the data voltage received from the display driver 200 to the plurality of data lines DL.

The plurality of gate control lines GCL may extend from the display driver 200 to the gate driver 210. The plurality of gate control lines GCL may supply the gate control signal received from the display driver 200 to the gate driver 210. In the drawing, it is illustrated that the gate driver 210 is disposed only in the non-display area NDA disposed on the left side of the display area DA, but the present disclosure is not limited thereto. In another embodiment, the display device 10 may include a plurality of gate drivers 210 respectively disposed on the left side and the right side of the display area DA.

The display panel 100 may include the display driver 200 and the plurality of display pads PD overlapping the pad area PDA of the sub-region SBA.

The display driver 200 may output signals and voltages for driving the display panel 100 to the fan-out lines FOL. The display driver 200 may supply a data voltage to the data line DL through the fan-out lines FOL. The data voltage may be supplied to the plurality of pixels PX, and the luminance of the plurality of pixels PX may be controlled thereby. The display driver 200 may supply the gate control signal to the gate driver 210 through the gate control lines GCL.

The plurality of display pads PD may be connected to a graphic system through the circuit board 300. The plurality of display pads PD may be connected to the circuit board 300 to receive digital video data and may supply the digital video data to the display driver 200.

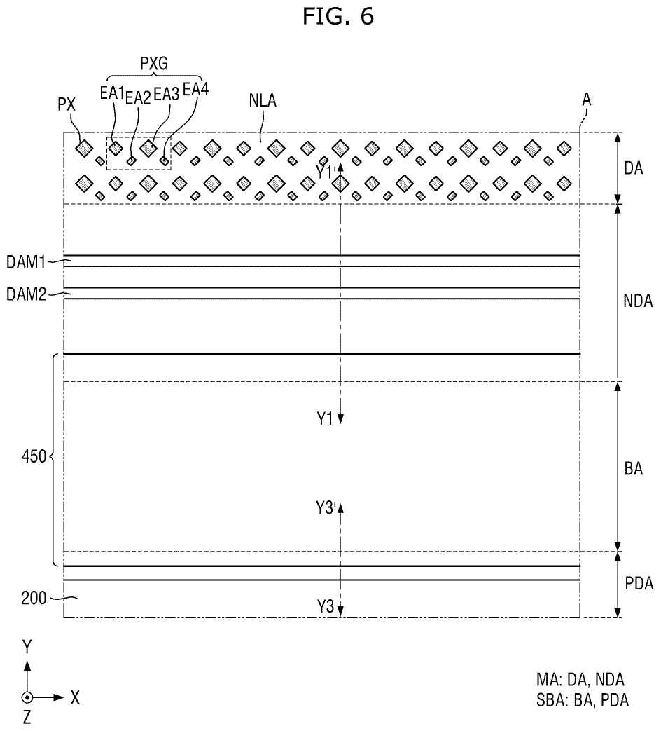

FIG. 6 is an enlarged plan view of the area ‘A’ in FIG. 5.

Referring to FIG. 6, the plurality of emission areas EA1, EA2, EA3, and EA4 and a non-emission area NLA may be disposed in the display area DA of the main region MA.

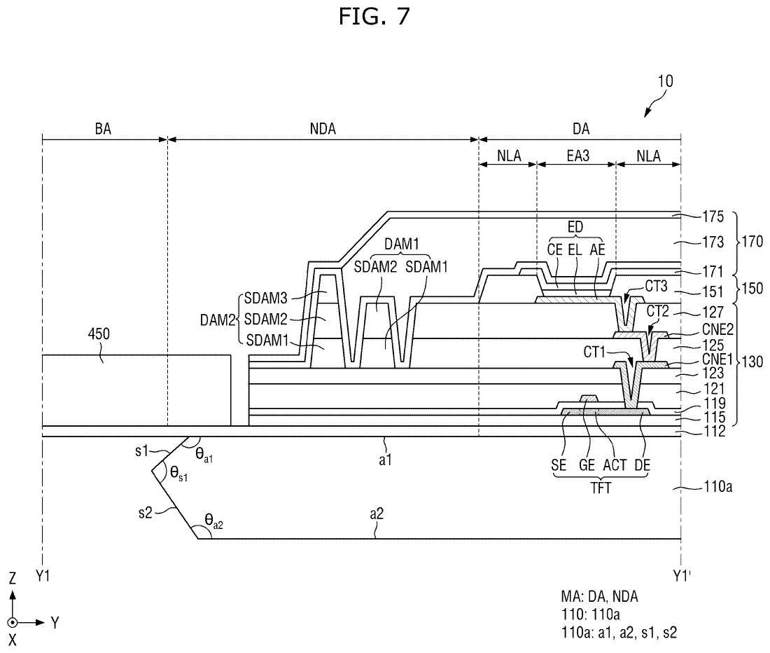

The non-emission area NLA may be located to surround the plurality of emission areas EA1, EA2, EA3, and EA4. A pixel defining layer 151 (see, e.g., FIG. 7), to be described later, may be disposed in the non-emission area NLA. The plurality of emission areas EA1, EA2, EA3, and EA4 may be defined by the pixel defining layer 151. The non-emission area NLA may prevent colors of the light emitted from the plurality of emission areas EA1, EA2, EA3, and EA4 from mixing.

The plurality of emission areas EA1, EA2, EA3, and EA4 may include the first emission area EA1 emitting light of a first color, the second emission area EA2 and the fourth emission area EA4 emitting light of a second color, and the third emission area EA3 emitting light of a third color. For example, light of the first color may be light in a red wavelength band in a range of approximately 600 nm to approximately 750 nm, light of the second color may be light in a green wavelength band in a range of approximately 480 nm to approximately 560 nm, and light of the third color may be light in a blue wavelength band in a range of approximately 370 nm to approximately 460 nm, but the present disclosure is not limited thereto.

The plurality of pixels PX including at least one first emission area EA1, at least one second emission area EA2, at least one third emission area EA3, and at least one fourth emission area EA4 disposed adjacent to each other may constitute a single pixel group PXG. The pixel group PXG may be a minimum unit that emits white light. However, the types and/or numbers of the emission areas EA1, EA2, EA3, and EA4 constituting each pixel group PXG may be modified in various ways according to different embodiments.

Although FIG. 6 illustrates an embodiment in which the second emission area EA2 and the fourth emission area EA4 emit light of the same color, that is, light of the second color, the present disclosure is not limited thereto. The second emission area EA2 and the fourth emission area EA4 may emit light of different colors. For example, the second emission area EA2 may emit light of the second color, and the fourth emission area EA4 may emit light of a fourth color. In addition, although it is illustrated that each of the first emission areas EA1, the second emission areas EA2, the third emission areas EA3, and the fourth emission areas EA4 has a rectangular planar shape, the present disclosure is not limited thereto. Each of the first emission areas EA1, the second emission areas EA2, the third emission areas EA3, and the fourth emission areas EA4 may have a polygonal shape other than a quadrilateral shape, a circular shape, or an elliptical shape in a plan view.

In some embodiments, the second emission areas EA2 and the fourth emission areas EA4 may be alternately disposed in the first direction (e.g., the X-axis direction). The plurality of second emission areas EA2 may be arranged in the second direction (e.g., the Y-axis direction), and the plurality of fourth emission areas EA4 may be arranged in the second direction (e.g., the Y-axis direction). In addition, the first emission areas EA1 and the third emission areas EA3 may be alternately disposed in the first direction (e.g., the X-axis direction). The plurality of first emission areas EA1 may be arranged in the second direction (e.g., the Y-axis direction), and the plurality of third emission areas EA3 may be arranged in the second direction (e.g., the Y-axis direction). Each of the first emission areas EA1 and the third emission areas EA3 may have a square planar shape, but the present disclosure is not limited thereto.

A first dam DAM1 and a second dam DAM2 may be disposed in the non-display area NDA of the main region MA in an embodiment. The first dam DAM1 and the second dam DAM2 may be structures for preventing an organic layer applied onto the display area DA from overflowing into the sub-region SBA. Accordingly, the first dam DAM1 and the second dam DAM2 may surround (e.g., may surround in a plan view) the display area DA. The second dam DAM2 may be disposed outside the first dam DAM1. For example, the second dam DAM2 may surround the first dam DAM1. The first dam DAM1 may be disposed closer to the display area DA than the second dam DAM2 is, and the second dam DAM2 may be disposed closer to the sub-region SBA than the first dam DAM1 is.

FIG. 6 illustrates an embodiment in which the display panel 100 includes two dams DAM1 and DAM2, but the present disclosure is not limited thereto. In some embodiments, the display panel 100 may include three or more dams.

As described above, the bending protection layer 450 may be disposed in a portion overlapping the non-display area NDA, the bending area BA, and the pad area PDA, and the display driver 200 may be disposed in a portion overlapping the pad area PDA. The bending protection layer 450 may be spaced apart from the first dam DAM1 and the second dam DAM2 on one side in the second direction (e.g., the Y-axis direction) and may be spaced apart from the display driver 200 on the other side in the second direction (e.g., the Y-axis direction). For example, the bending protection layer 450 may be positioned between the second dam DAM2 and the display driver 200.

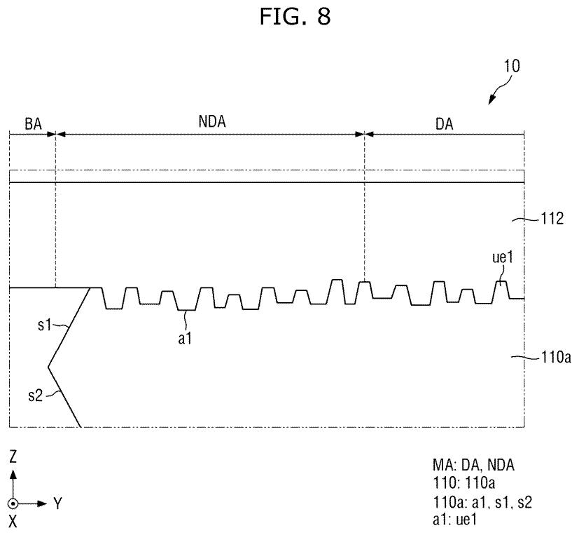

FIG. 7 is a schematic cross-sectional view of the display panel 100 taken along the line Y1-Y1′ in FIG. 6. FIG. 8 is an enlarged cross-sectional view illustrating a top surface a1 of the first sub-substrate 110a shown in FIG. 7.

FIG. 7 shows a schematic cross-sectional shape of the main region MA adjacent to the bending area BA. As described above, the first substrate 110, according to an embodiment, may include the first sub-substrate 110a overlapping the main region MA.

In some embodiments, the first sub-substrate 110a may have the top surface a1 and a bottom surface a2. The top surface a1 of the first sub-substrate 110a may be a surface in contact with the second substrate 112, and the bottom surface a2 of the first sub-substrate 110a may be a surface opposite to the top surface a1. The top surface a1 of the first sub-substrate 110a may extend to the first inclined surface s1, and the bottom surface a2 of the second sub-substrate 110b may extend to the second inclined surface s2. For example, the top surface a1 and the bottom surface a2 of the first sub-substrate 110a may be extended by (e.g., may be continuous with) the first inclined surface s1 and the second inclined surface s2.

In some embodiments, an inclination angle θa₁ formed between the first inclined surface s1 and the top surface a1 of the first sub-substrate 110a and an inclination angle θa₂ formed between the second inclined surface s2 and the bottom surface a2 of the first sub-substrate 110a may be obtuse angles. In addition, an inclination angle θs₁ formed between the first inclined surface s1 and the second inclined surface s2 may be an acute angle, an obtuse angle, or a right angle. The size of the inclination angle θs₁ formed between the first inclined surface s1 and the second inclined surface s2 may be adjusted by an etching process of the bending area BA during the manufacturing process of the display device 10.

Referring to FIG. 8, the top surface a1 of the first sub-substrate 110a, in an embodiment, may include an uneven structure ue1. The uneven structure ue1, according to an embodiment, may be disposed in a portion overlapping the display area DA and the non-display area NDA. In an embodiment, the uneven structure ue1 may extend to the first inclined surface s1.

Generally, when the display panel 100 is bent at the bending area BA, a high bending stress may be applied to a portion of the display panel 100. For example, when the display panel 100 is bent at the bending area BA, a high bending stress may be applied to a portion of the display panel 100 overlapping the non-display area NDA adjacent to the bending area BA. As a result, the first substrate 110 and the second substrate 112 may be detached from each other at that portion of the display panel 100. Further, the detachment of the first substrate 110 and the second substrate 112 located near the bending area BA may gradually expand, causing a defect that occurs the first substrate 110 and the second substrate 112 are also detached in another portion overlapping the main region MA. The detachment between the first substrate 110 and the second substrate 112 may cause cracks and poor reliability of the display device 10.

The display device 10, according to an embodiment, may increase an adhesive area between the first substrate 110 and the second substrate 112 by forming the uneven structure ue1 on (or in) the top surface a1 by laser processing on the first sub-substrate 110a. Accordingly, even if a bending stress is generated in a portion adjacent to the bending area BA when the display panel 100 is bent, the first sub-substrate 110a and the second substrate 112 may be supported by the uneven structure ue1. For example, the display device 10, according to an embodiment, can prevent detachment between the substrates, crack generation, and poor reliability of the display device 10 that might be caused when the display panel 100 is bent.

As illustrated in FIG. 8, the uneven structure ue1, according to an embodiment, may be in the form of randomly arranged irregularities rather than a shape in which protrusions and recesses are repeated in a regular array or pattern. A laser processing process included in an embodiment may include a process using an ultra-high-speed laser. As an example, the laser processing process, according to an embodiment, may include processes using a nanosecond laser, a picosecond laser, and a femtosecond laser. For example, the uneven structure ue1, according to an embodiment, may have a root mean square (RMS) roughness of about 3.5 nm or more when the surface thereof is measured using an atomic force microscopy (AFM) measurement device.

For example, the top surface a1 of the first sub-substrate 110a, according to an embodiment, may include the uneven structure ue1 in the portion overlapping the display area DA and the non-display area NDA of the main region MA, and the surface roughness of the uneven structure ue1 may have a value of about 3.5 nm or more. Accordingly, in the display device 10, according to an embodiment, adhesion between the first substrate 110 and the second substrate 112 may be enhanced and detachment between the first substrate 110 and the second substrate 112 may be prevented when the display panel 100 is bent.

The second substrate 112 may be positioned on the first sub-substrate 110a. The second substrate 112 may be completely in contact with the first sub-substrate 110a along the profile of the uneven structure ue1 included in (or formed in) the top surface a1 of the first sub-substrate 110a. Accordingly, in the display device 10, according to an embodiment, the adhesion between the first sub-substrate 110a and the second substrate 112 may be enhanced at the portion overlapping the display area DA and the non-display area NDA of the main region MA. Other redundant descriptions of the second substrate 112 will be omitted here.

Referring to FIG. 7, the thin film transistor layer 130 may be positioned on the second substrate 112. The thin film transistor layer 130 may include a buffer layer 115, a gate insulating layer 119, a thin film transistor TFT, a first insulating layer 121, a second insulating layer 123, a first connection electrode CNE1, a second connection electrode CNE2, a first via layer 125, and a second via layer 127.

The buffer layer 115 may be disposed on the second substrate 112. The buffer layer 115 may be formed of an inorganic material, such as a silicon nitride layer, a silicon oxynitride layer, a silicon oxide layer, a titanium oxide layer, and an aluminum oxide layer. In another embodiment, the buffer layer 115 may be formed as a multilayer structure in which a plurality of layers selected from a silicon nitride layer, a silicon oxynitride layer, a silicon oxide layer, a titanium oxide layer, and an aluminum oxide layer are alternately stacked.

The thin film transistor TFT may be disposed on the buffer layer 115. The thin film transistor TFT may include a gate electrode GE, an active layer ACT, a source region SE, and a drain region DE. The active layer ACT may be formed of polycrystalline silicon, monocrystalline silicon, low-temperature polycrystalline silicon, amorphous silicon, or an oxide semiconductor material. The source region SE and the drain region DE may be conductive regions doped with ions or impurities to have conductivity.

The gate insulating layer 119 may be disposed on the active layer ACT of the thin film transistor TFT. The gate insulating layer 119 may separate the gate electrode GE from the active layer ACT. The gate insulating layer 119 may be formed of an inorganic layer, for example, a silicon nitride layer, a silicon oxynitride layer, a silicon oxide layer, a titanium oxide layer, or an aluminum oxide layer.

The gate electrode GE of the thin film transistor TFT may be disposed on the gate insulating layer 119. The gate electrode GE of the thin film transistor TFT may overlap the active layer ACT in the third direction (e.g., the Z-axis direction). The gate electrode GE may be formed as a single layer or multiple layers made of any one of molybdenum (Mo), aluminum (AI), chromium (Cr), gold (Au), titanium (Ti), nickel (Ni), neodymium (Nd), and copper (Cu), or an alloy thereof.

The first insulating layer 121 may be disposed on the gate electrode GE. The first insulating layer 121 may be formed of an inorganic layer, for example, a silicon nitride layer, a silicon oxynitride layer, a silicon oxide layer, a titanium oxide layer, or an aluminum oxide layer. The first insulating layer 121 may include a plurality of inorganic layers. The first insulating layer 121 may include a first contact hole (e.g., a first contact opening) CT1.

The second insulating layer 123 may be disposed on the first insulating layer 121. The second insulating layer 123 may be formed of an inorganic layer, for example, a silicon nitride layer, a silicon oxynitride layer, a silicon oxide layer, a titanium oxide layer, or an aluminum oxide layer. The second insulating layer 123 may include the first contact hole CT1.

The first connection electrode CNE1 may be disposed on the second insulating layer 123. The connection electrode CNE1 may be connected to the drain region DE through the first contact hole CT1 penetrating (or extending through) the gate insulating layer 119, the first insulating layer 121, and the second insulating layer 123. The first connection electrode CNE1 may be formed as a single layer or multiple layers made of any one of molybdenum (Mo), aluminum (Al), chromium (Cr), gold (Au), titanium (Ti), nickel (Ni), neodymium (Nd), and copper (Cu), or an alloy thereof.

The first via layer 125 may be positioned on the first connection electrode CNE1. The first via layer 125 may planarize the profile of the structure(s) therebelow. The first via layer 125 may be formed of an organic layer, such as an acryl resin, an epoxy resin, a phenolic resin, a polyamide resin, a polyimide resin, and the like.

The second connection electrode CNE2 may be disposed on the first via layer 125. The second connection electrode CNE2 may be connected to the first connection electrode CNE1 through a second contact hole (e.g., a second contact opening) CT2 penetrating the first via layer 125. The second connection electrode CNE2 may be formed as a single layer or multiple layers made of any one of molybdenum (Mo), aluminum (Al), chromium (Cr), gold (Au), titanium (Ti), nickel (Ni), neodymium (Nd), and copper (Cu), or an alloy thereof.

The second via layer 127 may be disposed on the second connection electrode CNE2. The second via layer 127 may be formed of an organic layer, such as an acryl resin, an epoxy resin, a phenolic resin, a polyamide resin, a polyimide resin, and the like.

All structures of the thin film transistor layer 130, in one embodiment, may overlap the uneven structure ue1 included in the top surface a1 of the first sub-substrate 110a in the third direction (e.g., the Z-axis direction).

The display element layer 150 may be disposed on the thin film transistor layer 130. The display element layer 150 of the display device 10, in an embodiment, may be disposed in a portion overlapping the display area DA of the main region MA. For example, the light emitting element ED of the display element layer 150 may be disposed in a portion overlapping the emission area EA1, EA2, EA3, or EA4, and the pixel defining layer 151 of the display element layer 150 may be disposed in a portion overlapping the non-emission area NLA. Although an embodiment in which the light emitting element ED overlaps the third emission area EA3 has been illustrated and described herein for simplicity of description, the respective light emitting elements ED overlapping the plurality of emission areas EA1, EA2, EA3, and EA4 may have the same structure and features.

The light emitting element ED may include a pixel electrode AE, alight emitting layer EL, and a common electrode CE. The light emitting element ED refers to a region in which the pixel electrode AE, the light emitting layer EL, and the common electrode CE are sequentially stacked, and a hole transmitted by the pixel electrode AE and an electron transmitted by the common electrode CE are combined with each other in the light emitting layer EL to emit light. In such an embodiment, the pixel electrode AE may be an anode electrode, and the common electrode CE may be a cathode electrode.

The pixel electrode AE may be formed on the second via layer 127. The pixel electrode AE may be connected to the second connection electrode CNE2 through a third contact hole (e.g., a third contact opening) CT3 penetrating the second via layer 127. The pixel electrode AE may be formed as a single layer or multiple layers made of any one of molybdenum (Mo), aluminum (Al), chromium (Cr), gold (Au), titanium (Ti), nickel (Ni), neodymium (Nd), and copper (Cu), or an alloy thereof.

The pixel defining layer 151 may be formed on the second via layer 127 to expose a partial area of the pixel electrode AE. The pixel defining layer 151 may be disposed in the third contact hole CT3. For example, the third contact hole CT3 may be filled with the pixel defining layer 151. The pixel defining layer 151 may be formed of an organic layer, such as acryl resin, epoxy resin, phenolic resin, polyamide resin, polyimide resin, and the like.

The light emitting layer EL may be formed on the pixel electrode AE. The light emitting layer EL may include an organic material to emit light in a certain color (e.g., a predetermined color). For example, the light emitting layer EL may include a hole transporting layer, an organic material layer, and an electron transporting layer. The organic material layer may include a host and a dopant. The organic material layer may include a material that emits light and may be formed by using a phosphorescent material or a fluorescent material. The light emitting layer EL may overlap each of the plurality of emission areas EA1, EA2, EA3, and EA4 (see, e.g., FIG. 5), and the individual portions of the light emitting layer EL respectively overlapping the plurality emission areas EA1 to EA4 may be disposed to be spaced apart from each other.

The common electrode CE is formed on the light emitting layer EL. The common electrode CE may be formed to cover the light emitting layer EL. The common electrode CE may be a common layer, which is commonly formed in (or over) the plurality of emission areas EA1, EA2, EA3, and EA4.

The common electrode CE may be formed of a transparent conductive material (TCO), such as ITO or IZO, that can transmit light or a semi-transmissive conductive material, such as magnesium (Mg), silver (Ag), or an alloy of Mg and Ag. When the common electrode CE is formed of a semi-transmissive conductive material, the light emission efficiency can be increased by using a micro-cavity effect.

All the structures of the display element layer 150, in one embodiment, may overlap the uneven structure ue1 included in the top surface a1 of the first sub-substrate 110a in the third direction (e.g., the Z-axis direction).

Referring to FIG. 7, the first dam DAM1 and the second dam DAM2 of the display device 10 may be disposed to overlap the non-display area NDA. The first dam DAM1 and the second dam DAM2 may be positioned on the second insulating layer 123. As described above, the first dam DAM1 and the second dam DAM2 may be structures for preventing the organic layer applied on the display area DA from overflowing into the sub-region SBA.

The first dam DAM1 may include a first sub-dam SDAM1 and a second sub-dam SDAM2, and the second dam DAM2 may include a first sub-dam SDAM1, a second sub-dam SDAM2, and a third sub-dam SDAM3. The first sub-dam SDAM1 and the first via layer 125 may include the same material and may be disposed on the same layer. The second sub-dam SDAM2 and the second via layer 127 may include the same material and may be disposed on the same layer. The third sub-dam SDAM3 and the pixel defining film 190 may include the same material and may be disposed on the same layer.

The height of the first dam DAM1 may be lower than the height of the second dam DAM2, but the present disclosure is not limited thereto. The height of the first dam DAM1 may be substantially the same as the height of the second dam DAM2 or may be higher than the height of the second dam DAM2.

The first dam DAM1 and the second dam DAM2, in one embodiment, may overlap the uneven structure ue1 included in the top surface a1 of the first sub-substrate 110a in the third direction (e.g., the Z-axis direction).

The thin film encapsulation layer 170 may be positioned to overlap the display area DA and the non-display area NDA. The thin film encapsulation layer 170 may prevent oxygen or moisture from permeating into the display element layer 150 in the portion overlapping the display area DA and may cover the first dam DAM1 and the second dam DAM2 in the portion overlapping the non-display area NDA. The thin film encapsulation layer 170 may include a first encapsulation layer 171 and a third encapsulation layer 175 formed of an inorganic layer, and a second encapsulation layer 173 formed of an organic layer. The first encapsulation layer 171 may be disposed on the common electrode CE, the second encapsulation layer 173 may be disposed on the first encapsulation layer 171, and the third encapsulation layer 175 may be the second encapsulation layer 173. As described above, the second encapsulation layer 173 may not flow to the outside of the second dam DAM2 due to the presence of the second dam DAM2.

The first encapsulation layer 171 and the third encapsulation layer 175 may be formed as a multilayer structure in which one or more inorganic layers of a silicon nitride layer, a silicon oxynitride layer, a silicon oxide layer, a titanium oxide layer, and an aluminum oxide layer are alternately stacked. The second encapsulation layer 173 may be an organic layer, including, for example an acryl resin, an epoxy resin, a phenolic resin, a polyamide resin, a polyimide resin, or the like.

All the structures of the thin film encapsulation layer 170, in one embodiment, may overlap the uneven structure ue1 included in the top surface a1 of the first sub-substrate 110a in the third direction (e.g., the Z-axis direction).

The bending protection layer 450 may be disposed to overlap the non-display area NDA and the bending area BA. As described above, when the display panel 100 is bent, the bending protection layer 450 may protect the structure disposed to overlap the bending area BA and the perimeter of the bending area BA from a bending stress.

In some embodiments, the bending protection layer 450 may overlap the first inclined surface s1 and the second inclined surface s2 included in the first sub-substrate 110a in the third direction (e.g., the Z-axis direction), and the bending protection layer 450 may overlap the uneven structure ue1 included in the top surface a1 of the first sub-substrate 110a in the third direction (e.g., the Z-axis direction).

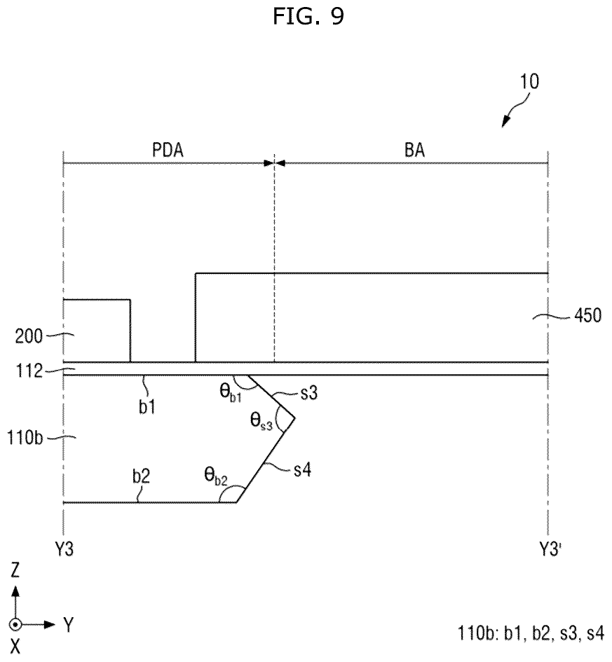

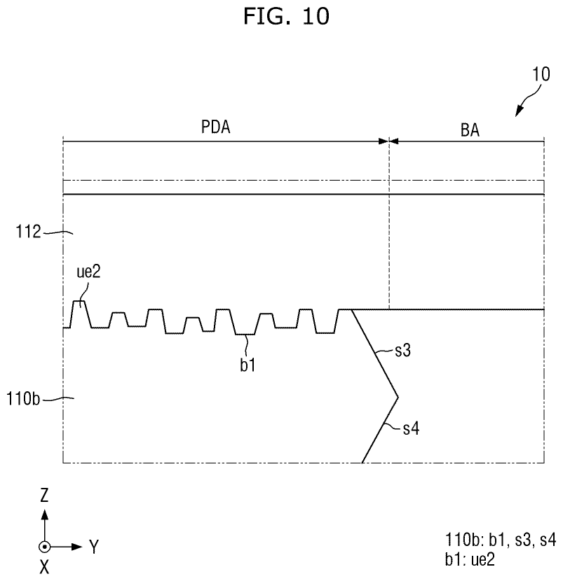

FIG. 9 is a cross-sectional view of the display device taken along the line Y3-Y3′ in FIG. 6. FIG. 10 is an enlarged cross-sectional view illustrating a top surface b1 of the second sub-substrate 110b shown in FIG. 9.

Referring to FIG. 9, the second sub-substrate 110b may have the top surface b1 and a bottom surface b2. The top surface b1 of the second sub-substrate 110b may be a surface in contact with the second substrate 112, and the bottom surface b2 of the second sub-substrate 110b may be a surface opposite to the top surface b1. The top surface b1 of the second sub-substrate 110b may extend to the first inclined surface s3, and the bottom surface b2 of the second sub-substrate 110b may extend to the second inclined surface s4. For example, the top and bottom surfaces b1 and b2 of the second sub-substrate 110b may be extended by (e.g., may be continuous with) the first inclined surface s3 and the second inclined surface s4.

An inclination angle θb1 formed between the first inclined surface s3 and the top surface b1 of the second sub-substrate 110b, and an inclination angle θb₂ formed between the second inclined surface s4 and the bottom surface b2 of the second sub-substrate 110b may be obtuse angles. In addition, the inclination angle θs₃ formed between the first inclined surface s3 and the second inclined surface s4 may be an acute angle, an obtuse angle, or a right angle. The inclination angle θs₃ formed by the first inclined surface s3 and the second inclined surface s4 may be adjusted by the etching process of the bending area BA during the manufacturing process of the display device 10. The first inclined surface s3 and the second inclined surface s4 of the second sub-substrate 110b may overlap the second substrate 112 and the bending protection layer 450 in the third direction (e.g., the Z-axis direction).

Referring to FIG. 10a, the top surface b1 of the second sub-substrate 110b, in one embodiment may include an uneven structure ue2. The uneven structure ue2, according to one embodiment, may be disposed in a portion overlapping the pad area PDA. In one embodiment, the uneven structure ue2 may extend to the first inclined surface s3.

Generally, when the display panel 100 is bent at the bending area BA, a high bending stress may be applied to a portion of the display panel 100. As an example, when the display panel 100 is bent at the bending area BA, a high bending stress may be applied to a portion of the display panel 100 overlapping the pad area PDA adjacent to the bending area BA. As a result, the first substrate 110 and the second substrate 112 may be detached at that portion of the display panel 100. The detachment between the first substrate 110 and the second substrate 112 may cause cracks and poor reliability of the display device 10.

The display device 10, in one embodiment, may enlarge the adhesive area between the first substrate 110 and the second substrate 112 by forming the uneven structure ue2 on the top surface b1 through laser processing on the second sub-substrate 110b. Accordingly, even if the display panel 100 overlapping the bending area BA is bent and a bending stress is generated in the portion overlapping the pad area PDA adjacent to the bending area BA, the second sub-substrate 110b and the second substrate 112 may be supported by the uneven structure ue2. For example, the display device 10, according to one embodiment, can prevent detachment between the substrates, crack generation, and poor reliability of the display device 10 that might be caused when the display panel 100 is bent.

The uneven structure ue2, according to one embodiment, may be in the form of randomly arranged irregularities rather than a shape in which protrusions and recesses in a regular array are repeated. The laser processing process, included in one embodiment, may include a process using an ultra-high-speed laser. As an example, the laser processing process, according to an embodiment, may include processes using a nanosecond laser, a picosecond laser, and a femtosecond laser.

In some embodiments, the uneven structure ue1 included in the top surface a1 of the first sub-substrate 110a and the uneven structure ue2 included in the top surface b1 of the second sub-substrate 110b may be formed in the same process. However, because a portion of the first substrate 110 overlapping the bending area BA is removed by a subsequent etching process, the uneven structure ue1 and the uneven structure ue2 may be separated from each other.

Therefore, the uneven structure ue2 included in the upper surface b1 of the second sub-substrate 110b may also have a root mean square (RMS) roughness of about 3.5 nm or more when the surface thereof is measured using an AFM measurement device.

Referring to FIGS. 9 and 10, the uneven structure ue2 included in the top surface b1 of the second sub-substrate 110b may overlap the bending protection layer 450 and the display driver 200 in the third direction (e.g., the Z-axis direction).

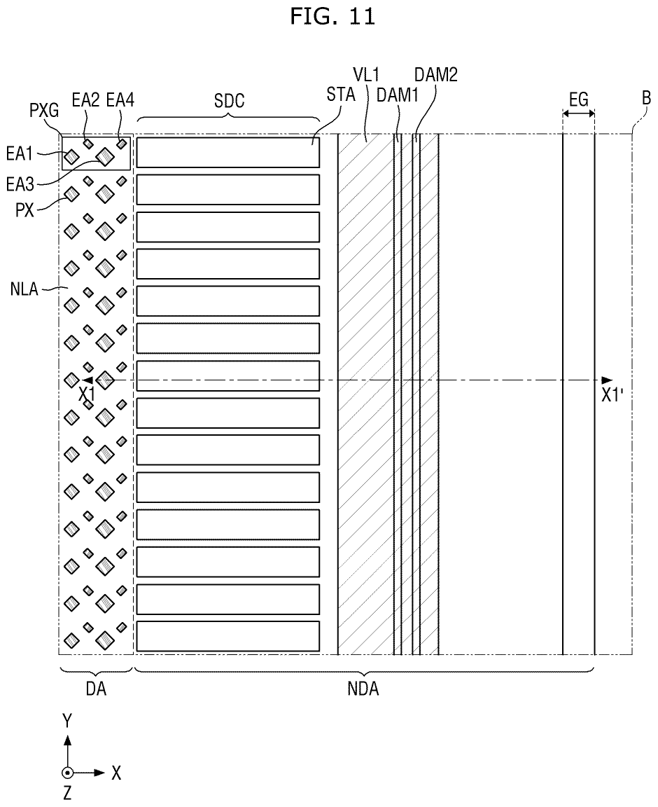

FIG. 11 is an enlarged plan view of the area ‘B’ in FIG. 5. FIG. 11 is a cross-sectional view showing a portion overlapping one end of the main region MA of the display device 10 in the first direction (e.g., the X-axis direction).

Referring to FIG. 11, the plurality of emission areas EA1, EA2, EA3, and EA4 and the non-emission area NLA may be located in the display area DA. A description thereof will be omitted as it has already been described with reference to FIG. 6.

A scan driver SDC, the first power line VL1, the first dam DAM1, and the second dam DAM2 may be disposed in the non-display area NDA, according to an embodiment.

The scan driver SDC may include a plurality of stages STA. The plurality of stages STA may extend in the first direction (e.g., the X-axis direction) to be respectively connected to scan lines located in the display area DA. For example, the plurality of stages STA may be connected to the scan lines in the display area DA in a one-to-one correspondence. The plurality of stages STA may sequentially apply scan signals to the plurality of scan lines.

The first power line VL1 may be disposed outside the scan driver SDC. For example, the first power line VL1 may be disposed closer to the edge portion EG of the display panel 100 than the scan driver SDC. The first power line VL1 may extend in the second direction (e.g., the Y-axis direction) in the non-display area NDA on the left side of the display panel 100.

The first power line VL1 may be electrically connected to the plurality of pixels PX located in the display area DA so that the plurality of pixels PX may be supplied with a power voltage.

Although FIG. 11 illustrates an embodiment in which the first dam DAM1 and the second dam DAM2 are disposed on the first power line VL1, the present disclosure is not limited thereto. For example, either one of the first dam DAM1 and the second dam DAM2 may not be disposed on (e.g., may be offset from) the first power line VL1. In another embodiment, neither the first dam DAM1 nor the second dam DAM2 may be disposed on the first power line VL1. In such an embodiment, the first dam DAM1 and the second dam DAM2 may be disposed outside the first power line VL1. Although FIG. 11 illustrates an embodiment in which the display panel 100 includes two dams DAM1 and DAM2, the present disclosure is not limited thereto. In some embodiments, the display panel 100 may include three or more dams. The edge portion EG of the display panel 100 may be a portion surrounding the outer portion of the display device 10 while overlapping the non-display area NDA. Other redundant descriptions will be omitted.

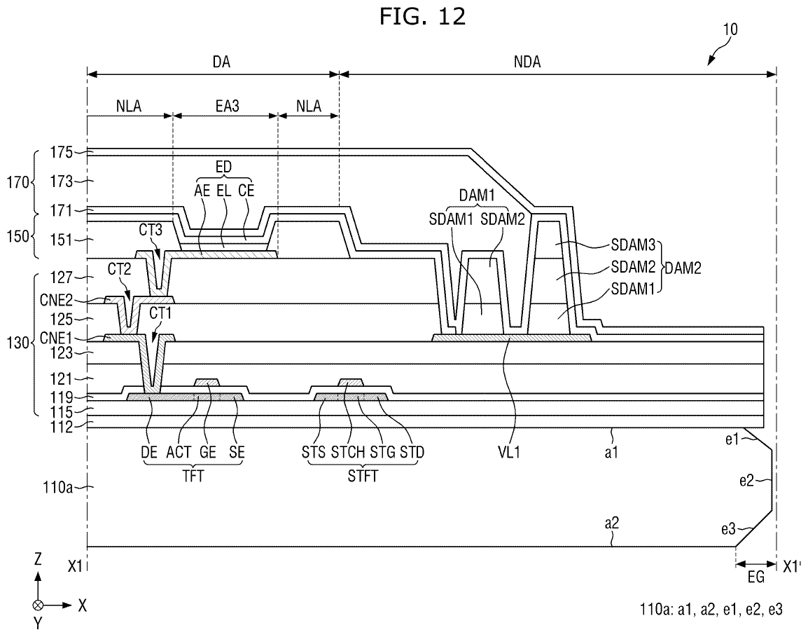

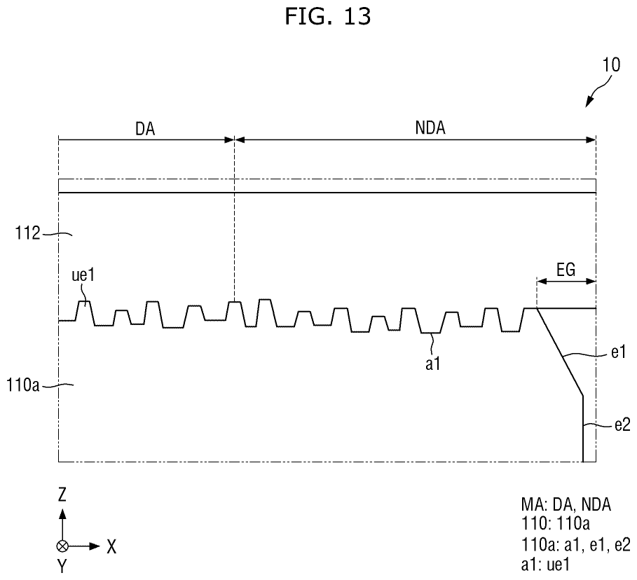

FIG. 12 is a cross-sectional view of a display device taken along the line X1-X1′ in FIG. 11. FIG. 13 is an enlarged cross-sectional view illustrating a top surface of a first sub-substrate shown in FIG. 12. FIG. 12 illustrates a schematic cross-sectional shape of one end of the main region MA in the first direction (e.g., the X-axis direction).

Referring to FIG. 12, the first sub-substrate 110a may have the top surface a1 and the bottom surface a2. The top surface a1 of the first sub-substrate 110a may extend to the first edge surface e1 at an area overlapping the edge portion EG of the display panel 100, and the bottom surface a2 of the first sub-substrate 110a may extend to the third edge surface e3 at an area overlapping the edge portion EG of the display panel 100. In addition, the first edge surface e1 and the third edge surface e3 may be connected by the second edge surface e2. For example, the top and bottom surfaces a1 and a2 of the first sub-substrate 110a may be extended by the first edge surface e1, the second edge surface e2, and the third edge surface e3.

Referring to FIG. 13, the top surface a1 of the first sub-substrate 110a, according to one embodiment, may include the uneven structure ue1. In one embodiment, the uneven structure ue1 may extend to the first edge surface e1.

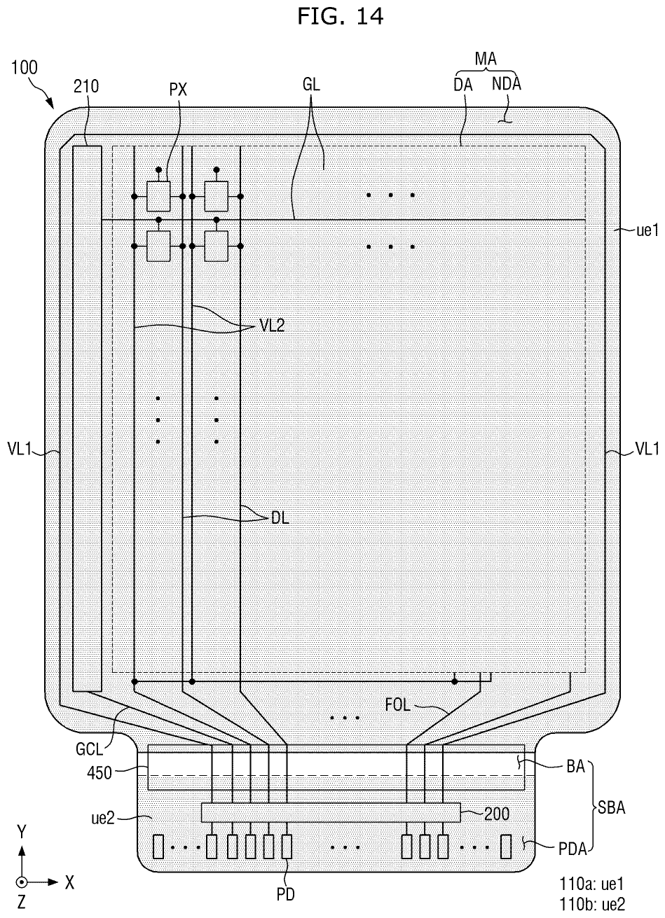

The uneven structure ue1, according to one embodiment, may be disposed in a portion overlapping the display area DA and the non-display area NDA. For example, the uneven structure ue1 included in the first sub-substrate 110a of the display device 10, according to one embodiment, may be formed on the entire surface of the portion overlapping the display area DA and the non-display area NDA. This will be explained again later with reference to a plan view shown in FIG. 14.

The second substrate 112 may be disposed on the first sub-substrate 110a. The second substrate 112 may be completely in contact with the first sub-substrate 110a along the profile of the uneven structure ue1 included in the first sub-substrate 110a. Accordingly, in the display device 10, in one embodiment, adhesion between the first sub-substrate 110a and the second substrate 112 may be improved in the portion overlapping the display area DA and the non-display area NDA of the main region MA. Other redundant parts of the description of the second substrate 112 will be omitted.

Referring to FIG. 12, the thin film transistor layer 130 may be disposed on the second substrate 112. The thin film transistor layer 130 according to one embodiment may include, on the buffer layer 115, a scan thin film transistor STFT of the scan driver SDC. The scan thin film transistor STFT may be substantially the same as the thin film transistor TFT. For example, the scan thin film transistor STFT may include a scan gate electrode STCH, a scan active layer STG, a scan source region STS, and a scan drain region STD. The scan active layer STG may be formed of polycrystalline silicon, monocrystalline silicon, low-temperature polycrystalline silicon, amorphous silicon, or an oxide semiconductor material. The scan source region STS and the scan drain region STD may be conductive regions doped with ions or impurities to have conductivity. The scan gate electrode STCH and the scan active layer STG may be spaced apart from each other by the gate insulating layer 119.

All the structures of the thin film transistor layer 130, in an embodiment, may overlap the uneven structure ue1 included in the top surface a1 of the first sub-substrate 110a in the third direction (e.g., the Z-axis direction).

The display element layer 150 and the thin film encapsulation layer 170 may be disposed on the thin film transistor layer 130, and the structure and characteristics of the display element layer 150 and the thin film encapsulation layer 170 may be the same as described with reference to FIG. 7. Other redundant descriptions will be omitted.

FIG. 14 is a plan view illustrating a schematic structure where an uneven structure of a first substrate overlaps in a plan view.

Referring to FIG. 14, in a plan view, the uneven structure ue1 included in the first sub-substrate 110a, according to an embodiment, may be disposed on the entire surface of the portion overlapping the main region MA of the display panel 100. In other words, the uneven structure ue1, according to one embodiment, may be positioned on the entire surface of the portion overlapping the display area DA and the non-display area NDA of the main region MA. In addition, in a plan view, the uneven structure ue2 included in the second sub-substrate 110b, according to an embodiment, may be disposed on the entire surface of the portion overlapping the pad area PDA of the display panel 100.

In a plan view, the uneven structure ue1 included in the first sub-substrate 110a and the uneven structure ue2 included in the second sub-substrate 110b may not overlap the bending area BA. For example, in a plan view, the uneven structure ue1 included in the first sub-substrate 110a and the uneven structure ue2 included in the second sub-substrate 110b, according to an embodiment, may overlap all the portions except the bending area BA.

The display device 10, according to an embodiment, may include the bending protection layer 450 overlapping the non-display area NDA, the bending area BA, and the pad area PDA in a plan view. Accordingly, in a plan view, the bending protection layer 450 may overlap the uneven structure ue1 included in the first sub-substrate 110a and the uneven structure ue2 included in the second sub-substrate 110b in the third direction (e.g., the Z-axis direction).

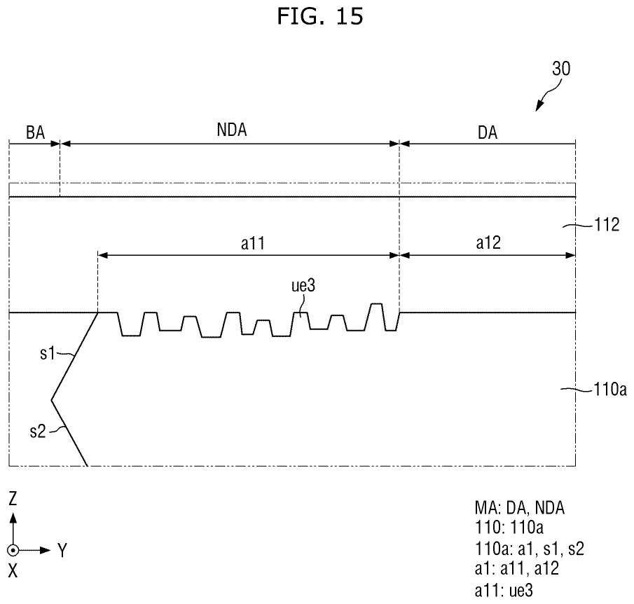

FIG. 15 is an enlarged cross-sectional view illustrating the top surface of the first sub-substrate shown in FIG. 7 according to another embodiment.

Referring to FIG. 15, a display device 30 differs from the display device 10, described above, in that the top surface a1 of the first sub-substrate 110a of the display device 30 includes a first portion a11 and a second portion a12.

In some embodiments, the first portion a11 of the top surface a1 included in the first sub-substrate 110a may be a portion that does not overlap the display area DA but overlaps the non-display area NDA. For example, the first portion a11, according to an embodiment, may be disposed on the entire surface of the non-display area NDA of the main region MA.

In one embodiment, the first portion a11 may include an uneven structure ue3. In one embodiment, the uneven structure ue3 may extend to the first inclined surface s1 facing the bending area BA. The uneven structure ue3, according to one embodiment, may be in the form of randomly arranged irregularities rather than a shape in which protrusions and recesses are repeated in a regular array. The uneven structure ue3, according to one embodiment, may have a root mean square (RMS) roughness of about 3.5 nm or more when the surface thereof is measured using an AFM measurement device. The uneven structure ue3, according to one embodiment, may increase the contact area between the first sub-substrate 110a and the second substrate 112 so that a defect that occurs when the first sub-substrate 110a and the second substrate 112 are detached when the display panel 100 is bent may be prevented.

The uneven structure ue3, according to one embodiment, may be formed through a laser processing process in a manufacturing process of the display device 30. The laser processing process included in one embodiment may be the same process as the laser processing process for the uneven structure ue1 included in the display device 10. However, the laser processing process of the display device 30, according to an embodiment, is performed in a manner of overlapping the non-display area NDA of the main region MA without overlapping the display area DA of the main region MA, which is different from the display device 10 described above.

In some embodiments, the second portion a12 of the top surface a1 included in the first sub-substrate 110a may be a portion overlapping the display area DA. In one embodiment, the second portion a12 of the top surface a1 may not include the uneven structure ue3. For example, the second portion a12, according to one embodiment, may be a portion that has not been (or is not) laser processed.

Therefore, the uneven structure ue3 of the first sub-substrate 110a included in the display device 30 may not overlap the plurality of structures overlapping the display area DA. As an example, the uneven structure ue3 of the first sub-substrate 110a included in the display device 30 may not overlap the thin film transistor layer 130 overlapping the display area DA, the display element layer 150 overlapping the display area DA, and the thin film encapsulation layer 170 overlapping the display area DA.

The second sub-substrate 110b of the display device 30, according to an embodiment, may have the same structure and characteristics as the second sub-substrate 110b included in the display device 10 described in FIGS. 9 and 10. For example, the second sub-substrate 110b, according to an embodiment, may include the top surface b1 facing the second substrate 112, and the top surface b1 of the second sub-substrate 110b may include the uneven structure ue2 on the entire surface of the portion overlapping the pad area PDA. Other redundant descriptions will be omitted.

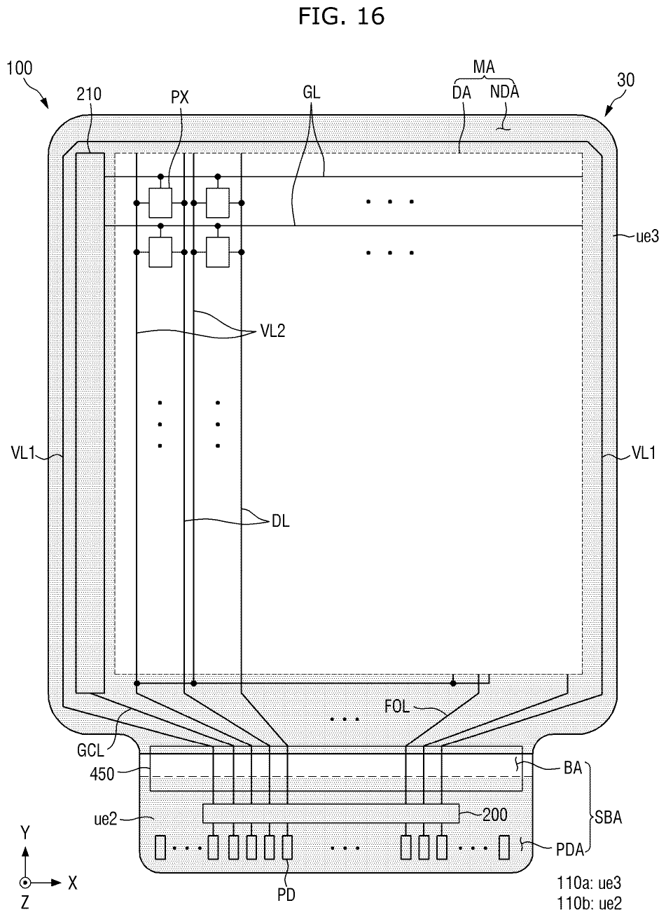

FIG. 16 is a plan view illustrating a schematic structure where the uneven structure included in the first substrate 110 show in FIG. 15 overlaps in a plan view.

Referring to FIG. 16, in a plan view, the uneven structure ue3 included in the first sub-substrate 110a, according to an embodiment, may be disposed on the entire surface of the portion overlapping the non-display area NDA, and the uneven structure ue3, according to an embodiment, may not overlap the display area DA. For example, in a plan view, the uneven structure ue3, according to an embodiment, may be disposed in a mesh shape surrounding (e.g., extending around) the display area DA. In addition, in a plan view, the uneven structure ue2 included in the second sub-substrate 110b, according to an embodiment, may include the uneven structure ue2 overlapping the entire surface of the pad area PDA.

In a plan view, the uneven structure ue3 included in the first sub-substrate 110a and the uneven structure ue2 included in the second sub-substrate 110b, according to an embodiment, may not overlap the bending area BA.

The display device 30, according to an embodiment, may include the bending protection layer 450 overlapping the non-display area NDA, the bending area BA, and the pad area PDA in a plan view. Accordingly, in a plan view, the bending protection layer 450, according to an embodiment, may overlap the uneven structure ue3 included in the first sub-substrate 110a and the uneven structure ue2 included in the second sub-substrate 110b in the third direction (e.g., the Z-axis direction).

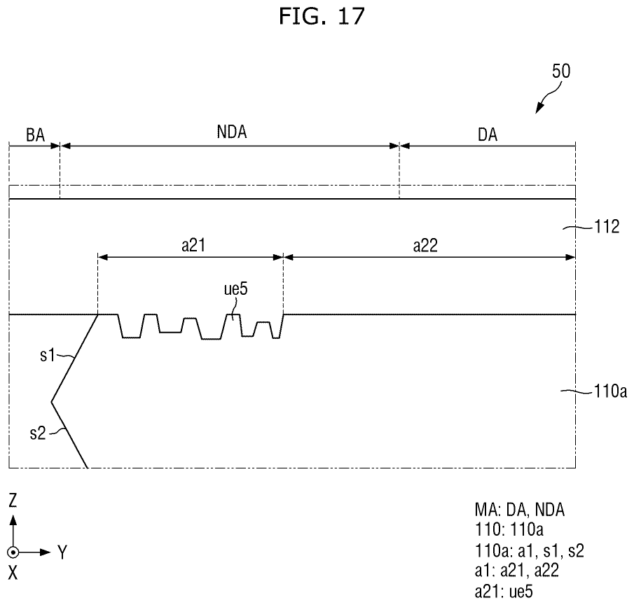

FIG. 17 is an enlarged cross-sectional view illustrating the top surface a1 of the first sub-substrate 110a shown in FIG. 7 according to another embodiment.

Referring to FIG. 17, the top surface a1 of the first sub-substrate 110a included in a display device 50, according to an embodiment, may include a first portion a21 and a second portion a22.

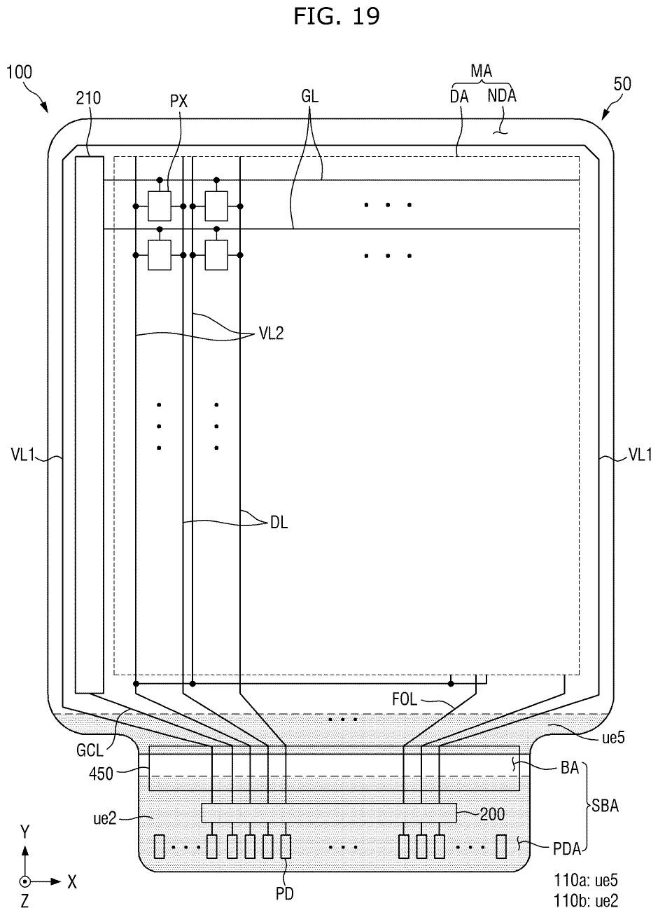

The first portion a21 of the top surface a1, in an embodiment, may not overlap the display area DA. In addition, the first portion a21, according to an embodiment, is disposed to overlap a part of the non-display area NDA without overlapping the entire surface of the non-display area NDA, which is different from the display device 30 described above. In addition, the first portion a21, according to an embodiment, may be disposed only in a portion of the non-display area NDA located close to the bending area BA, which will be explained again later with reference to a plan view shown in FIG. 19.

In one embodiment, the first portion a21 may include an uneven structure ue5. In one embodiment, the uneven structure ue5 may extend to the first inclined surface s1 facing the bending area BA. In one embodiment, the uneven structure ue5 may be in the form of randomly arranged irregularities rather than a shape in which protrusions and recesses are repeated in a regular array. The uneven structure ue5, according to an embodiment, may have a root mean square (RMS) roughness of about 3.5 nm or more when the surface thereof is measured using an AFM measurement device. As stated above, the uneven structure ue5, according to an embodiment, may enlarge the contact area between the first sub-substrate 110a and the second substrate 112 so that a defect that occurs when the first sub-substrate 110a and the second substrate 112 are detached when the display panel 100 is bent may be prevented.

The uneven structure eu5, according to an embodiment, may be formed through a laser processing process during a manufacturing process of the display device 50. The laser processing process included in one embodiment may be the same process as the laser processing process for the uneven structure ue1 included in the display device 10 and the uneven structure ue3 included in the display device 30. However, the laser processing process included in the display device 50, according to an embodiment, is performed in a manner overlapping a portion of the non-display area NDA adjacent to the bending area BA, which is spaced from the display device 10 and the display device 30 of the other embodiments.

Therefore, the uneven structure ue5 of the first sub-substrate 110a included in the display device 50, according to one embodiment, may not overlap the plurality of structures overlapping the display area DA. As an example, the uneven structure ue5 of the first sub-substrate 110a included in the display device 50 may not overlap the thin film transistor layer 130 overlapping the display area DA, the display element layer 150 overlapping the display area DA, and the thin film encapsulation layer 170 overlapping the display area DA.

The second sub-substrate 110b of the display device 50, in one embodiment, may have the same structure and characteristics as the second sub-substrate 110b included in the display device 10 as described above with reference to FIGS. 9 and 10. For example, the second sub-substrate 110b, according to an embodiment, may include the top surface b1 facing the second substrate 112, and the top surface b1 of the second sub-substrate 110b may include the uneven structure ue2 on the entire surface of the portion overlapping the pad area PDA. Other redundant descriptions will be omitted.

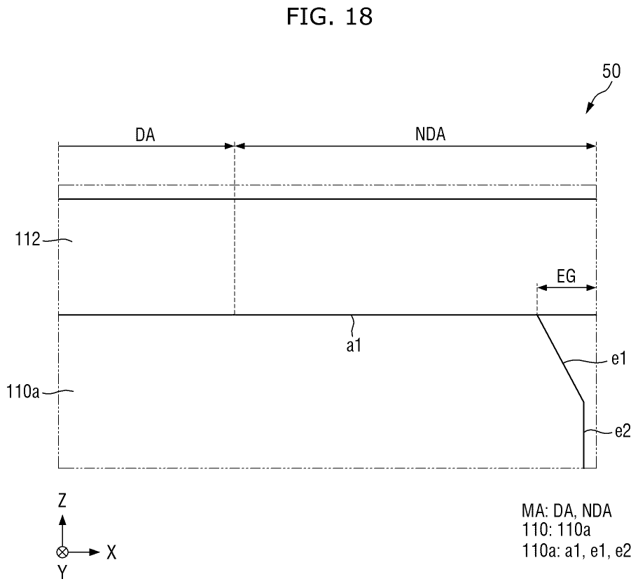

FIG. 18 is an enlarged cross-sectional view illustrating the top surface a1 of the first sub-substrate 110a shown in FIG. 12 according to another embodiment. FIG. 18 is an enlarged cross-sectional view showing a portion overlapping one end of the main region MA in the first direction (e.g., the X-axis direction).

Referring to FIG. 18, the display device 50, according to an embodiment, may be different from the display device 10 and the display device 30 described above in that the top surface a1 of the first sub-substrate 110a of the display device 50 does not include an uneven structure overlapping one end of the main region MA in the first direction (e.g., the X-axis direction). A portion at where the uneven structure eu5 overlaps will be described again with reference to the plan view shown in FIG. 19.

FIG. 19 is a plan view showing a schematic structure where an uneven structure included in the first substrate of FIGS. 17 and 18 overlaps.

Referring to FIG. 19, in a plan view, the uneven structure ue5 included in the first sub-substrate 110a, according to an embodiment, may be located in a portion of the non-display area NDA adjacent to the bending area BA. For example, the uneven structure ue5, according to one embodiment, may not overlap one end and the other end of the main region MA in the first direction (e.g., the X-axis direction) of the main region MA and may not overlap one end of the main region MA in the second direction (e.g., the Y-axis direction). For example, the uneven structure ue5, according to an embodiment, may be positioned to overlap the other end of the main region MA in the second direction (e.g., the Y-axis direction), that is, to overlap only a portion of the non-display area NDA located at the other end of the main region MA in the second direction (e.g., the Y-axis direction).

In a plan view, the uneven structure ue2 included in the second sub-substrate 110b, according to an embodiment, may be disposed in a portion overlapping the pad area PDA. For example, in the display device 50, according to an embodiment, the first sub-substrate 110a includes the uneven structure ue5 overlapping a portion of the non-display area NDA adjacent to the bending area BA in a plan view, and the second sub-substrate 110b includes the uneven structure ue2 overlapping the pad area PDA in a plan view. Therefore, a defect that occurs when the first substrate 110 and the second substrate 112 are detached when the display panel 100 is bent may be prevented.

In a plan view, the display device 50, according to an embodiment, may include the bending protection layer 450 overlapping the non-display area NDA, the bending area BA, and the pad area PDA. Accordingly, in a plan view, the bending protection layer 450 may overlap the uneven structure ue5 included in the first sub-substrate 110a and the uneven structure ue2 included in the second sub-substrate 110b in the third direction (e.g., the Z-axis direction).

Features of various embodiments of the present disclosure may be combined partially or totally. As will be clearly appreciated by those skilled in the art, technically various interactions and operations are possible. Also, various embodiments can be practiced individually or in combination.

In concluding the detailed description, those skilled in the art will appreciate that many variations and modifications can be made to the described embodiments without departing from the present disclosure. Therefore, the disclosed embodiments of the present disclosure are used in a generic and descriptive sense and not for purposes of limitation.

What is claimed is:

1. A display device comprising:
a first substrate having a main region, a pad area, and a bending area between the main region and the pad area;
a thin film transistor layer on the main region of the first substrate; and
a second substrate on the main region and the pad area of the first substrate at a side opposite to a side where the thin film transistor layer is arranged,
wherein the second substrate comprises a first sub-substrate overlapping the main region and a second sub-substrate spaced apart from the first sub-substrate with the bending area therebetween and overlapping the pad area, the first sub-substrate having:
a first surface facing the first substrate;
a second surface opposite to the first surface;
a first inclined surface facing the bending area and extending to the first surface; and
a second inclined surface extending between the second surface and the first inclined surface,
wherein an inclination angle formed between the first surface and the first inclined surface and an inclination angle formed between the second surface and the second inclined surface are obtuse angles, and
wherein the first surface has an uneven structure.

2. The display device of claim 1, wherein the uneven structure of the first surface does not overlap the bending area.

3. The display device of claim 2, wherein the uneven structure of the first surface has a shape in which protrusions and recesses are randomly arranged.

4. The display device of claim 1, wherein the first substrate and the second substrate are in contact with each other.

5. The display device of claim 4, wherein a contact area between the first substrate and the second substrate is increased due to the uneven structure of the first surface.

6. The display device of claim 4, wherein the uneven structure has a root mean square roughness of 3.5 nm or more.

7. The display device of claim 1, further comprising a bending protection layer on the bending area of the first substrate, wherein the bending protection layer overlaps the first inclined surface and the second inclined surface in a direction normal to the first substrate.

8. The display device of claim 7, wherein the bending protection layer overlaps the main region, and
wherein the bending protection layer overlaps the uneven structure of the first surface in the direction normal to the first substrate.

9. The display device of claim 7, wherein the second sub-substrate has:
a third surface facing the first substrate;
a fourth surface opposite to the third surface;
a third inclined surface facing the bending area and extending to the third surface; and
a fourth inclined surface extending between the fourth surface and the third inclined surface,
wherein an inclination angle formed between the third surface and the third inclined surface and an inclination angle formed between the fourth surface and the fourth inclined surface are obtuse angles, and
wherein the third surface has an uneven structure.

10. The display device of claim 9, wherein the third inclined surface and the fourth inclined surface face the first inclined surface and the second inclined surface.

11. The display device of claim 10, wherein the bending protection layer overlaps the pad area, and
wherein the uneven structure of the third surface overlaps the bending protection layer in a direction normal to the first substrate.

12. The display device of claim 1, wherein the second substrate has a first edge surface overlapping an end of the first substrate and extending to the first surface, and
wherein an undercut is formed between the first edge surface and the first substrate.

13. The display device of claim 12, wherein an inclination angle formed between the first surface and the first edge surface inside the second substrate is an obtuse angle.

14. The display device of claim 1, wherein the second substrate has a thickness of 200 μm or less.

15. A display device comprising:
a first substrate having a main region comprising a display area and a non-display area, a pad area, and a bending area between the non-display area and the pad area;
a display element layer on the display area of the first substrate; and
a second substrate on the first substrate on a side opposite to a side where the display element layer is arranged, the second substrate comprising:
a first sub-substrate overlapping the main region, the first sub-substrate having a first surface facing the first substrate and having an uneven structure; and
a second sub-substrate overlapping the pad area and spaced apart from the first sub-substrate with the bending area therebetween, the second sub-substrate having a second surface facing the first substrate and having an uneven structure, and
wherein, in a plan view, the uneven structure of the first surface and the uneven structure of the second surface are spaced apart from each other with the bending area therebetween.

16. The display device of claim 15, wherein the first surface has a first portion having the uneven structure and a second portion that does not have the uneven structure, and
wherein the first portion overlaps the non-display area, and the second portion overlaps the display area.

17. The display device of claim 16, wherein the first portion does not overlap the display area in the plan view, and
wherein the first portion has a mesh shape in the plan view.

18. The display device of claim 15, wherein the uneven structure of the first surface overlaps the display area, and
wherein, in the plan view, the uneven structure of the first surface overlaps the display element layer in a direction normal to the first substrate.

19. The display device of claim 15, further comprising a bending protection layer on the non-display area, the bending area, and the pad area of the first substrate,
wherein, in the plan view, the bending protection layer overlaps the uneven structure of the first surface and the uneven structure of the second surface in a direction normal to the first substrate.

20. The display device of claim 15, wherein the first substrate and the second substrate are in contact with each other, and
wherein the uneven structure increases an adhesive area between the first substrate and the second substrate.
